(19) United States
(12) Patent Application Publication
(10) Pub. No.: US 2012/0292733 A1
(43) Pub. Date: Nov. 22, 2012

(54) Mixed Schottky/P-N Junction Diode and Method of Making

(75) Inventors: Dongping Wu, Shanghai (CN); Shi-Li Zhang, Stockholm (SE); Yinghua Pu, Shanghai (CN)

(73) Assignee: FUDAN UNIVERSITY, Shanghai (CN)

(21) Appl. No.: 13/255,501

(22) PCT Filed: Jan. 4, 2011
(86) PCT No.: PCT/CN11/00014

§ 371 Date: Sep. 8, 2011

(30) Foreign Application Priority Data
Jan. 21, 2010 (CN) 201010023066.4

(51) Int. Cl. H01L 29/872; H01L 21/329

(52) U.S. Cl. 257/472; 257/471; 438/572; 438/581; 438/583; 257/E29.338; 257/E21.359

(57) ABSTRACT

The present invention relates to the field of microelectronic technology. It discloses a mixed Schottky/P-N junction diode and a method of making the same. The mixed Schottky/P-N junction diode comprises a semiconductor substrate having a bulk region and a doped region, and a conductive layer on the semiconductor substrate. The doped region has opposite doping from that of the bulk region. A P-N junction is formed between the bulk region and the doped region, a Schottky junction is formed between the conductive layer and the semiconductor substrate, and an ohmic contact is formed between the conductive layer and the doped region. The mixed Schottky/P-N junction diode of the present invention has high operating current, fast switching speed, small leakage current, high breakdown voltage, ease of fabrication and other advantages.

### TECHNICAL FIELD

The present invention is related to microelectronic technologies, and more particularly to diodes and method of making diodes.

### BACKGROUND

Two differently doped regions can be formed in a block of semiconductor using diffusion, alloying, ion implantation and other fabrication processes. One of the doped regions becomes donor-dominated N-type semiconductor, while the other one of the doped regions becomes acceptor-dominated P-type semiconductor. A metallurgical boundary between the P-type region and the N-type region is called a P-N junction.

The P-N junction has the characteristic of unilateral conduction. When a forward biased voltage is above a threshold voltage, the P-N junction begins to conduct, and current increases exponentially with respect to the voltage. When a reverse biased voltage is applied to the P-N junction, leakage current can be small and saturates. The leakage current increases abruptly when the reverse biased voltage is above a breakdown voltage, causing a breakdown phenomenon.

The P-N junction has certain capacitive effect, depending on two factors, potential barrier capacitor and diffusion capacitor. In equilibrium, charges exist in a potential barrier region of the P-N junction. The width of the potential barrier region decreases as positive bias is applied, causing majority carriers to flow into a space-charged area, resembling the charging of a capacitor. On the other hand, the width of the potential barrier region increases when reverse bias is applied, causing the formation of a depletion region when charge carriers flow out of the space-charged region, resembling the discharging of a capacitor. Minority carriers in diffusion regions of the P-N junction also move according to voltage, and this behavior can also be considered as capacitive. The capacitor associated with the capacitive behavior of the minority carriers is the diffusion capacitor. Both the potential barrier capacitor and diffusion capacitor are non-linear capacitors.

Contacts between metal and semiconductor are divided into rectifying contacts and ohmic contacts. In fact, an ohmic contact is generally formed when the semiconductor has high dopant concentration, and it will exhibit low resistance whether positively biased voltage or negatively biased voltage is applied. On the contrary, a rectifying contact is formed when the semiconductor has low dopant concentration. The rectifying contact between a metal and a semiconductor is referred to as a Schottky contact.

The work function of a semiconductor is generally smaller than that of a metal. Therefore, when the metal contacts the semiconductor (e.g., a N-type semiconductor), electrons flow from the semiconductor into the metal, leaving the immobile positively charged dopant ions to form a space-charged region at the surface of the semiconductor. An electric field pointing from the semiconductor toward the metal exists in the space-charged region, forming a Schottky barrier. Electrons need to have energy higher than the barrier in order to move over the potential barrier into the metal. At equilibrium, the height of the Schottky barrier is about the difference in work function between the metal and the semiconductor. When positive voltage is applied to the metal, the electric field in the space-charged region decreases, lowering the potential barrier and making it easier for charge carriers to pass through. On the contrary, when the potential barrier increases, it is harder for charge carriers to pass through. Therefore, a Schottky junction has unilaterally conductive and rectifying characteristics.

When the bias voltage applied to a P-N junction suddenly changes direction, the minority carriers cannot be eliminated immediately, causing the switching speed to be limited by this minority carrier storage effect. On the other hand, current in the Schottky junction is conducted by majority carriers. Because no minority carriers are stored, minority carrier life time can be omitted, and the frequency of the Schottky junction is mainly limited by its RC time constant. As a result, the switching time of a Schottky junction is more ideal.

Because majority carrier current is higher than minority carrier current, the saturation current in a Schottky junction is much higher than a P-N junction with the same cross-section area. Therefore, for a same amount of current, the positive voltage applied to the Schottky junction is lower than the P-N junction. On the other hand, the threshold voltage of the Schottky junction is lower than the P-N junction while the reverse current in the Schottky junction is higher than the P-N junction. Further, Schottky junctions often have extra leakage current and are susceptible to soft-breakdown, and thus are not suitable for making devices.

### SUMMARY

Based on the above, the present invention provides a diode that has fast switching speed, small leakage current, high breakdown voltage, and other advantages.

The present invention also provides a method of making the diode.

The diode provided by the present invention is a mixed Schottky/P-N junction diode. Its structure comprises a semiconductor substrate, a region A on the semiconductor substrate having opposite doping from that of the semiconductor substrate, and a conductive layer B. A P-N junction is formed between the semiconductor substrate and the region A. The conductive layer B contacts the semiconductor substrate and the region A. The conductive layer B forms a Schottky junction with the semiconductor substrate, and the conductive layer B forms an ohmic contact with the region A.

Preferably, the semiconductor substrate includes silicon, germanium, silicon-germanium alloy, a silicon-on-oxide (SOI) structure, or a germanium-on-oxide (GOI) structure. The semiconductor substrate has a dopant concentration between ×10¹⁴˜1×10¹⁹cm⁻³.

Preferably, the region A has a dopant concentration higher than the dopant concentration of the semiconductor substrate.

Preferably, the conductive layer B includes metal or a metal alloy formed by a metal and the semiconductor substrate.

Preferably, the metal alloy includes nickel silicide, nickel germanide, cobalt silicide, cobalt germanide, titanium silicide, titanium germanide, platinum silicide, platinum germanide, or a combination thereof.

The present invention provides a method of making a diode, comprising: growing an insulator layer on a semiconductor substrate and forming a window region in the insulator layer using photolithography and/or etching; depositing a blocking layer and removing a major portion of the blocking layer using anisotropic dry etching, leaving sidewalls formed by the blocking layer near edges of the window region; removing the sidewalls after forming a P-N junction on the semiconductor substrate using diffusion or ion implantation; depositing a metal layer over the semiconductor substrate and after annealing, removing part of the metal layer that has not reacted with the semiconductor substrate, leaving a conductive layer covering an entire window region.

Preferably, the semiconductor substrate includes silicon, germanium, silicon-germanium alloy, a silicon-on-oxide (SOI) structure, or a germanium-on-oxide (GOI) structure.

Preferably, the blocking layer and the insulator layer are made of different materials.

Preferably, the metal is nickel, cobalt, titanium, platinum or a combination thereof.

Preferably, the conductive layer includes nickel silicide, nickel germanide, cobalt silicide, cobalt germanide, titanium silicide, titanium germanide, platinum silicide, platinum germanide, or a combination thereof

The diode structure made using the method of the present invention includes mixed Schottky/P-N junction. The diode has high operating current, fast switching speed, small leakage current, high breakdown voltage, each of fabrication and other advantages.

These objectives, together with the content and features of the present invention, are explained in more details in the following with respect to the drawings.

### BRIEF DESCRIPTION OF THE DRAWINGS

FIG. 1 is a cross-sectional diagram illustrating a semiconductor substrate according to an embodiment of the present invention.

FIG. 2 is a cross-sectional diagram illustrating an insulator layer formed over the semiconductor substrate of FIG. 1.

FIG. 3 is a cross-sectional diagram illustrating a window region formed in the insulator layer of FIG. 2 using photolithography and/or etching.

FIG. 4 is a cross-sectional diagram illustrating a blocking layer formed over the structure shown in FIG. 3.

FIG. 5 is a cross-sectional diagram illustrating the structure shown in FIG. 4 after an etching process.

FIG. 6 is a cross-sectional diagram illustrating a P-N junction formed in the structure shown in FIG. 5.

FIG. 7 is a cross-sectional diagram illustrating the structure shown in FIG. 6 after removal of sidewalls.

FIG. 8 is a cross-sectional diagram illustrating a metal layer deposited over the structure shown in FIG. 7.

FIG. 9 is a cross-sectional diagram illustrating a mixed Schottky/P-N junction diode after completion of a fabrication process.

### DETAILED DESCRIPTION OF THE EMBODIMENTS

The structure of and the method of making the mixed Schottky/P-N junction diode provided by the present invention are described in more detail below with respect to the drawings. In the following description, same reference numerals are used to refer to same components, so as to save the trouble of repeated explanations. In the drawings, for ease of illustration, different layers, regions or components are enlarged or shrunk in different proportions, so their illustrated sizes are not to scale with actual sizes and do not represent proportional relationships of the actual sizes.

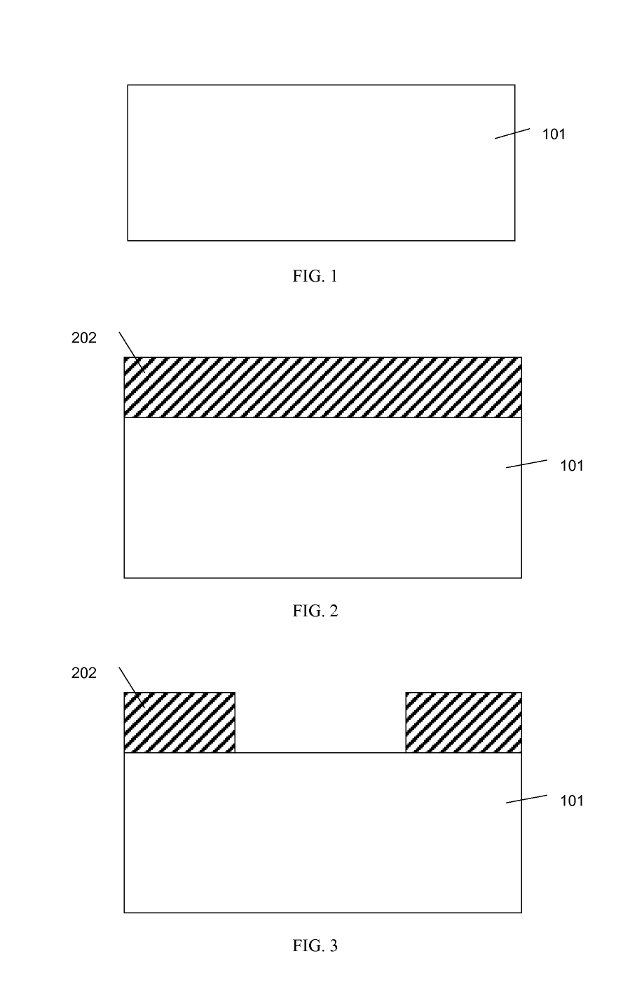

FIG. 1 is a cross-sectional diagram illustrating a semiconductor substrate according to an embodiment of the present invention. First, the semiconductor substrate 101 is prepared with various processes such as cleaning and native oxide removal, etc. In this embodiment, the semiconductor substrate includes single crystal silicon.

As illustrated in FIG. 2, an insulator layer 202, such as silicon dioxide or silicon nitride, is grown on the semiconductor substrate. Afterwards, a window is formed in a region where a diode is desired to be formed by removing part of the insulator layer using photolithography and/or etching, as illustrated in FIG. 3.

As illustrated in FIG. 4, a blocking layer 403 is formed on the semiconductor substrate. In order to have selectivity over the insulator layer 202 during subsequent removal of the blocking layer, the blocking layer 403 and the insulator layer 202 should be made of different materials.

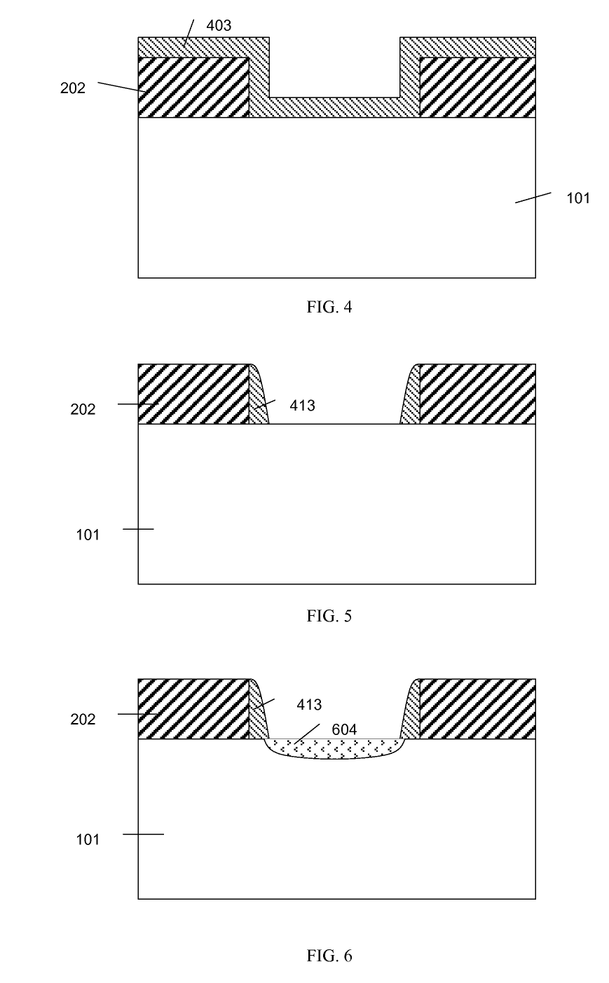

A majority portion of the blocking layer 403 is removed using dry etching, leaving only part of the blocking layer near edges of the window, as shown in FIG. 5. The blocking layer 403 after dry etching form sidewall structures 413 along edges of the window.

As illustrated in FIG. 6, diffusion or ion implantation can be used to form a doped region 604 at the surface of the semiconductor substrate 101. The doped region 604 has opposite doping from that of the semiconductor substrate 101 and higher dopant concentration than that of the semiconductor substrate 101. If the semiconductor substrate 101 is doped with N-type dopants, region 604 is highly doped with P-type dopants. If the semiconductor substrate 101 is doped with P-type dopants, region 604 is highly doped with N-type dopants. Thus, a P-N junction is formed between the newly formed doped region 604 and a bulk of the semiconductor substrate 101 other than the doped region 604.

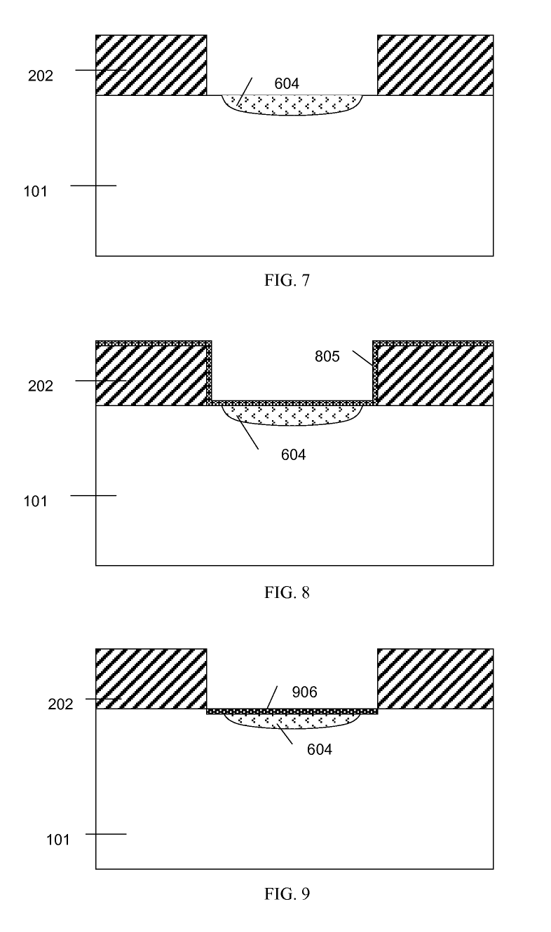

As illustrated in FIG. 7, the sidewalls 413 are removed using either dry etching or wet etching, exposing a surface of the semiconductor substrate at the bottom of the window.

Afterwards, as illustrated in FIG. 8, a metal layer 805 is formed over the semiconductor substrate. After annealing, unreacted portion of the metal layer is removed. As shown in FIG. 9, a metal silicide 906 is formed at the surface of the semiconductor substrate. The metal silicide 906 covers an entire surface of the semiconductor substrate at the bottom of the window, contacting both the bulk of the semiconductor substrate and the highly doped semiconductor region 604. Because the dopant concentration in the newly formed semiconductor region 604 is relatively high, doped region 604 forms ohmic contact with the metal silicide 906. On the other hand, the dopant concentration in the bulk of the semiconductor substrate 101 is relatively low, so the bulk of the semiconductor substrate 101 forms Schottky contact with the metal silicide 906. Metal 805 can be any of titanium, cobalt, nickel, platinum or any combination thereof. After annealing, metal silicide formed out of reactions between the metal 805 and the semiconductor substrate can be: nickel silicide, cobalt silicide, titanium silicide, platinum silicide, or a combination thereof. If the semiconductor substrate is germanium, metal germanide is formed from the metal 805 and the germanium substrate.

Without departing from the inventive spirit of the present invention, other fabrication processes can be used to form the metal silicide layer 906.

In the above embodiment, in order to ensure the formation of a Schottky junction between the metal silicide 906 and the substrate 101, an initial dopant concentration of the substrate 101 may need to be controlled in the range of 1×10¹⁴˜1×10¹⁹cm⁻³. In order to ensure the formation of ohmic contact between the metal silicide 906 and the newly formed highly doped region 604, the dopant concentration of the region 604 should generally be higher than 1×10¹⁹cm⁻³. It is important to note that the semiconductor substrate 101 is not limited to be a silicon substrate; it can include germanium, silicon-germanium alloy, SOI (silicon-on-insulator) structure, or a GOI (germanium-on-insulator) structure, etc.

The above described processes and methods can be rearranged during actual implementation. In other words, the above described process steps and methods can be appropriately adjusted during actual implementation without departing from the spirit of the invention. It is to be understood that except the limitations recited in the appended claims, the invention is not limited to the foregoing description of specific embodiments.

What is claimed is:

1. A mixed Schottky/P-N junction diode, characterized in that a structure of the diode comprises a semiconductor substrate, a region A on the semiconductor substrate having opposite doping from that of the semiconductor substrate, and a conductive layer B, a P-N junction being formed between the semiconductor substrate and the region A, the conductive layer B contacting the semiconductor substrate and the region A, the conductive layer B forming a Schottky junction with the semiconductor substrate, and the conductive layer B forming an ohmic contact with the region A.

2. The mixed Schottky/P-N junction diode of claim 1, wherein the semiconductor substrate includes silicon, germanium, silicon-germanium alloy, a silicon-on-oxide (SOI) structure, or a germanium-on-oxide (GOI) structure, and wherein a doping concentration of the semiconductor substrate is between 1×10¹⁴ cm⁻³ and 1×10¹⁹cm⁻³.

3. The mixed Schottky/P-N junction diode of claim 1, wherein the region A has a higher doping concentration than a doping concentration in the semiconductor substrate.

4. The mixed Schottky/P-N junction diode of claim 1, wherein the conductive layer B includes a metal or a metal alloy formed by a metal and the semiconductor substrate.

5. The mixed Schottky/P-N junction diode of claim 4, wherein the metal alloy is nickel silicide, nickel germanide, cobalt silicide, cobalt germanide, titanium silicide, titanium germanide, platinum silicide, platinum germanide, or a combination thereof

6. A method of making a mixed Schottky/P-N junction diode, comprising:
growing an insulator layer on a semiconductor substrate and forming a window region in the insulator layer using photolithography and etching;
depositing a blocking layer and removing a major portion of the blocking layer using anisotropic dry etching, leaving sidewalls formed by the blocking layer near edges of the window region;
removing the sidewalls after forming a P-N junction on the semiconductor substrate using diffusion or ion implantation;
depositing a metal layer over the semiconductor substrate and removing part of the metal layer not having reacted with the semiconductor substrate after annealing, leaving a conductive layer covering an entire surface of the semiconductor substrate in the window region.

7. The method of claim 6, wherein the semiconductor substrate includes silicon, germanium, silicon-germanium alloy, a silicon-on-oxide (SOI) structure, or a germanium-on-oxide (GOI) structure.

8. The method of claim 6, wherein the blocking layer and the insulator layer are made of different materials.

9. The method of claim 6, wherein the metal is nickel, cobalt, titanium, platinum or a combination thereof

10. The method of claim 6, wherein the conductive layer includes nickel silicide, nickel germanide, cobalt silicide, cobalt germanide, titanium silicide, titanium germanide, platinum silicide, platinum germanide, or a combination thereof.
